(19) United States
(12) Patent Application Publication
(10) Pub. No.: US 2009/0134415 A1
(43) Pub. Date: May 28, 2009

(54) LIGHT EMITTING ELEMENT AND METHOD FOR PRODUCING THE SAME

(75) Inventor: Tatsuya MORIOKA, Ikoma-shi (JP)

Correspondence Address: MORRISON & FOERSTER LLP, 1650 TYSONS BOULEVARD, SUITE 400, MCLEAN, VA, 22102, US

(73) Assignee: SHARP KABUSHIKI KAISHA, Osaka-shi (JP)

(21) Appl. No.: 12/274,150

(22) Filed: Nov. 19, 2008

(30) Foreign Application Priority Data
Nov. 27, 2007 (JP) 2007-306633

(51) Int. Cl. H01J 1/62; H05B 33/10; H01L 33/00

(52) U.S. Cl. 257/98; 445/3; 257/E33.061

(57) ABSTRACT

A light scattering section is formed on at least part of a surface of a sealing resin section including fluorescent bodies and covering light emitting diode chips. Light from the light emitting diode chips is scattered by the light scattering section, and then is returned to the sealing resin section so as to excite the fluorescent bodies so that fluorescence is generated. Part of the light to be emitted outside a light emitting element from the light emitting diode chips returns to the sealing resin section so that chromaticity of the light is converted by the fluorescent bodies, thereby adjusting a chromaticity variation among the light emitting elements. In this way, the chromaticity variation among the light emitting elements can be adjusted.

This Nonprovisional application claims priority under U.S.C. §119(a) on Patent Application No. 306633/2007 filed in Japan on Nov. 27, 2007, the entire contents of which are hereby incorporated by reference.

### FIELD OF THE INVENTION

The present invention relates to a light emitting element including a light emitting diode chip and a resin section for covering the light emitting diode chips and containing fluorescent bodies that are excitable by light from the light emitting diode chip.

### BACKGROUND OF THE INVENTION

A white light emitting element using a semiconductor light emitting element is expected to be applicable to market of bulb or tube-shaped lighting devices of the next generation such as an electric bulb used in a general lighting apparatus, a liquid crystal backlight, a fluorescent tube, a cold-cathode tube, and the like. Such a white light emitting element includes a light emitting diode chip covered with a resin or the like in which a fluorescent body is contained. The white light emitting element emits white light by using light from the light emitting diode chip and light from the fluorescent body excited by the light from the light emitting diode chip.

In response to an improvement in performance of individual element due to a technical development of blue light emitting diode and fluorescent body used in the white light emitting element, such a white light emitting element that is superior in luminous efficiency to the fluorescent bulb and the cold-cathode tube is becoming commercialized. However, the white light emitting element still has a problem in that its chromaticity widely varies compared to the fluorescent bulb, the cold-cathode tube, and the like, and therefore is required to have a chromaticity variation decreased to the same extent as the fluorescent bulb and the cold-cathode tube.

One of the reasons for the wide chromaticity variation in the white light emitting element is such that the production process of the white light emitting element requires, after a resin in which fluorescent bodies are dispersed is applied onto light emitting diode chips, a certain period of time to let the resin be completely cured. That is, because the fluorescent bodies are preliminarily dispersed in the resin, although the fluorescent bodies are evenly dispersed at the time of application of the resin, a time from when the application begins until when the whole resin is cured differs between a resin applied immediately after the beginning of the application and a resin applied at the end of the application. As a result, the fluorescent bodies are dispersed in different ways in the resins due to a precipitation and the like of the fluorescent bodies, thereby causing the variation in chromaticity.

Moreover, because viscosity of the resin is lower at a curing temperature (100° C. to 150° C.) of the resin compared to at a room temperature, the precipitation of the fluorescent bodies is more likely to occur so that the chromaticity widely varies. In addition, the chromaticity variation also attributes to matters such as a variation in weight measurement of the fluorescent bodies, the resin, and the like, and in dispersion of the fluorescent bodies caused at the time of application of the resin.

As a method for preventing such a chromaticity variation, Japanese Unexamined Patent Publication No. 2004-186488 (publication date: Jul. 2, 2004) discloses an arrangement that, after a resin including fluorescent bodies is cured, an optically-transparent resin not including the fluorescent bodies is applied on a surface of the cured resin. This makes it possible to control how much light from a light emitting diode chip is absorbed by the resin that does not substantially include the fluorescent bodies. Consequently, the chromaticity variation is adjusted by controlling an amount of light with which the fluorescent bodies are irradiated.

Further, Japanese Unexamined Patent Publication No. 2006-269757 (publication date: Oct. 5, 2006) discloses an arrangement that a fluorescent enamel layer including fluorescent bodies is formed on a surface of a substrate on which a light emitting diode chip is mounted so that the fluorescent bodies on the substrate surface will be excited by light from the light emitting diode chip so as to emit light. By this, the enamel layer including the fluorescent bodies has a comparatively small variation in dispersion of the fluorescent bodies at the time of production, thereby reducing the chromaticity variation.

However, with the arrangement in Japanese Unexamined Patent Publication No. 2004-186488, since the resin not including the fluorescent bodies is further applied to the surface of the resin including the fluorescent bodies, the whole resin covering the light emitting diode chip increases in thickness. As a result, the amount of light from the light emitting diode chip absorbed by the resin increases so that an amount of light emitted by a light emitting element decreases. Consequently, the light emitting element has a low light extraction efficiency. If the resin is arranged so as to be thinner in thickness for the purpose of preventing a decrease in the light extraction efficiency, it becomes impossible to adjust the chromaticity to a sufficient extent. On the other hand, if the resin is arranged so as to be thicker, there arises other problem that the resin becomes easier to peel off.

With the arrangement in Japanese Unexamined Patent Publication No. 2006-269757, since the fluorescent bodies exist only on the surface of the substrate on which the light emitting diode chip is mounted, an amount of light reaching the fluorescent bodies from the light emitting diode chip is limited. Consequently, an excitation of the fluorescent bodies becomes insufficient so that light from the fluorescent bodies cannot be obtained to a sufficient extent. As a result, it can be difficult to adjust the chromaticity to an arbitrary value.

The present invention has been accomplished in view of the problems above, and an object of the present invention is to achieve a light emitting element whose chromaticity variation is lowered without reducing a light extraction efficiency of the light emitting element.

### SUMMARY OF THE INVENTION

In view of the problems above, the light emitting element in accordance with the present invention is a light emitting element having light emitting diode chips and a first resin section including fluorescent bodies and covering the light emitting diode chips, the light emitting element having: a light scattering section provided on at least part of a surface of the first resin section, the light scattering section being configured to scatter light.

In view of the problems above, the method for producing the light emitting element in accordance with the present invention is a method for producing a light emitting element having light emitting diode chips and a first resin section including fluorescent bodies and covering the light emitting diode chips, the method including: forming a light scattering section on at least part of a surface of the first resin section, the light scattering section being configured to scatter light.

With the arrangement, since the light scattering section for scattering light is provided on at least part of the surface of the first resin section covering the light emitting diode chips, part of light to be emitted outside the light emitting element from the light emitting diode chips is scattered by the light scattering section and then is returned to the, first resin section. The light returned to the first resin section excites the fluorescent bodies so that fluorescence is generated.

As described above, in the present invention, it is possible to adjust a chromaticity variation in light emitted from the light emitting elements by controlling, with the light scattering section provided on the resin surface, an amount of light from the light emitting diode chips and that of light from the fluorescent bodies, in response to a difference with a desired chromaticity.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1 is a top view of a light emitting element in accordance with one embodiment of the present invention.

FIG. 2 is a top view showing an inside of the light emitting element shown in FIG. 1.

FIG. 3 is a view showing a cross-section across line A-A′ in the light emitting element shown in FIG. 1.

FIG. 4 is a chromaticity diagram showing a chromaticity variation in light from the light emitting elements shown in FIG. 1.

FIG. 5 is a cross-sectional view of a light emitting element in accordance with other embodiment of the present invention.

FIG. 6 is a top view showing an inside of the light emitting element shown in FIG. 5.

FIG. 7 is a chromaticity diagram showing a chromaticity variation among the light emitting elements shown in FIG. 5.

FIG. 8 is partial cross-sectional views of light emitting elements in accordance with another embodiment of the present invention.

FIG. 9 is top views of light emitting elements in accordance with still another embodiment of the present invention.

FIG. 10 is a schematic view showing a part of processes for forming a light emitting element in accordance with the present invention.

FIG. 11 is a schematic view showing a part of processes for forming a light emitting element in accordance with the present invention.

### DESCRIPTION OF THE EMBODIMENTS

### First Embodiment

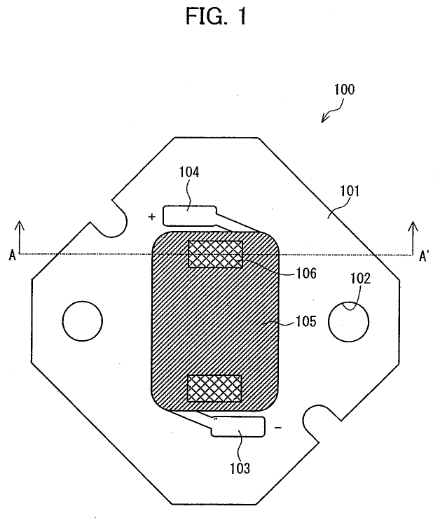

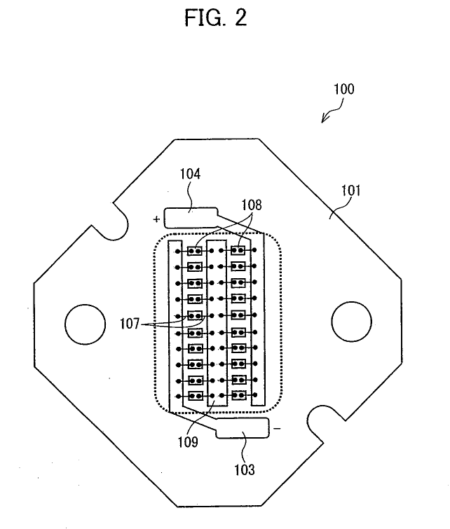

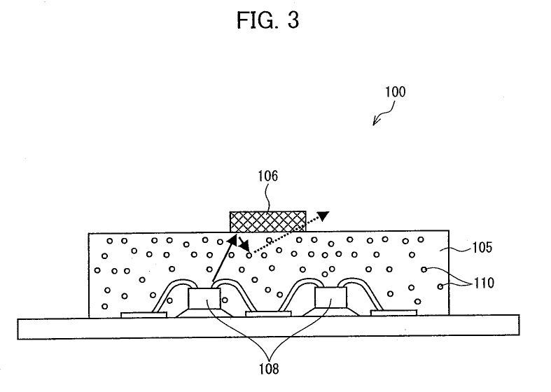

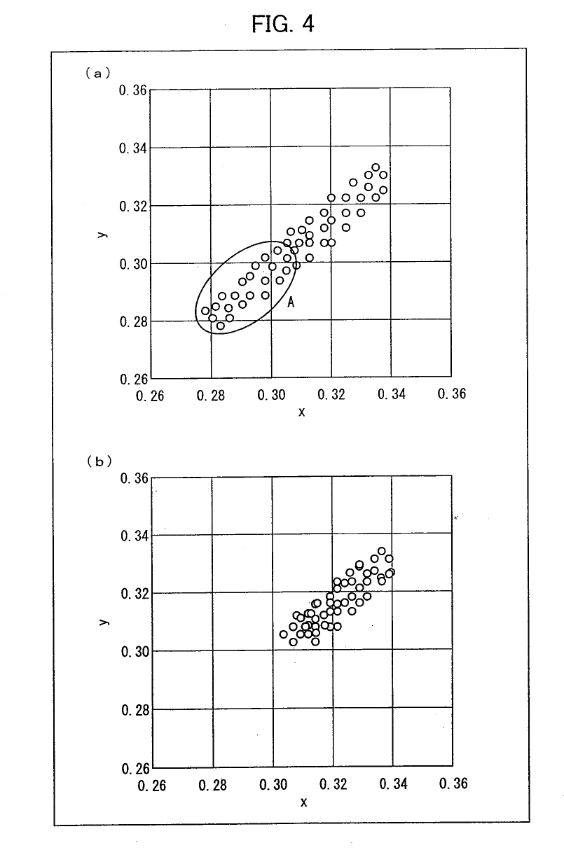

One embodiment of the light emitting element in accordance with the present invention is described below with reference to FIGS. 1 through 4. FIG. 1 is a top view of a light emitting element 100 in accordance with one embodiment of the present invention. FIG. 2 is a top view showing an inside of the light emitting element 100 shown in FIG. 1. FIG. 3 is a view showing a cross-section across line A-A′ in the light emitting element 100 shown in FIG. 1. FIG. 4 is a chromaticity diagram showing a chromaticity variation among the light emitting elements 100 shown in FIG. 1.

As shown in FIGS. 1 through 3, the light emitting element 100 has a substrate 101, mounting holes 102, a negative electrode pattern 103, a positive electrode pattern 104, a sealing resin section (a first resin section) 105, light scattering resin sections (second resin sections) 106, metal wires 107, light emitting diode chips 108, and an electrode pattern 109. The sealing resin section 105 is made of an optically-transparent resin material such as a silicon resin, and includes fluorescent bodies 110. The fluorescent bodies 110 are dispersed in the sealing resin section 105. The light scattering resin section 106 is made of a resin material, such as a silicon resin, including a light scattering material. The light scattering resin section 106 scatters light. The light scattering material is dispersed in the light scattering resin section 106. The light emitting element includes the light emitting diode chips 108, the sealing resin section 105, and the light scattering resin sections 106.

As shown in FIG. 1, the light emitting element 100 is used with being screwed on a lamp, a heat radiating fin, and the like via the mounting holes 102 formed on the substrate 101. In the present embodiment, the substrate 101 is an alumina substrate. The alumina substrate exhibits an excellent heat radiation with approximately 20 W/m·k heat conductivity, and has an extremely high reflectance ratio (approximately 90%) at a wavelength of visible light. Further, the substrate 101 has a size of 2 cm, and a thickness of 1 mm to 3 mm in view of heat radiation and mechanical strength. The mounting holes 102 are formed with a size appropriate for screwing the light emitting element. In the present embodiment, each of the mounting holes 102 is 3 mm in diameter.

As shown in FIG. 2, 20 of the light emitting diode chips 108 are die-bonded to substantially the central part of the substrate 101 with a silicon resin paste. Each of the light emitting diode chips 108 is a blue GaN light emitting diode chip formed on a sapphire substrate having an emission wavelength of 460 nm range, and has a size of 240 μm×480 μm and a thickness of approximately 100 μm.

Further, various electrode patterns 103, 104, and 109 are provided on the substrate 101. Such electrode patterns may be laminates of silver palladium of 5 μm thickness, nickel of 2 μm thickness, and gold of 0.5 μm thickness. On the substrate 101, 20 of the light emitting diode chips 108 are arrayed in two lines, each of which has 10 of the light emitting diode chips 108. Negative electrode sections (not shown) of the light emitting diode chips 108 in one line are wire-bonded to the negative electrode pattern 103, respectively, with the metal wires 107 each having a diameter of several tens of micrometers. Further, a negative electrode pad of the light emitting element is provided at the end of the negative electrode pattern 103. Likewise, positive electrode sections (not shown) of the light emitting diode chips 108 in another line are wire-bonded to the positive electrode pattern 104, respectively, with the metal wires 107 each having a diameter of several tens of micrometers. Further, a positive electrode pad of the light emitting element is provided at the end of the positive electrode pattern 104.

Moreover, the positive electrode sections (not shown) of the light emitting diode chips 108 in one line are electrically connected to the negative electrode sections (not shown) of the light emitting diode chips 108 in another line via the electrode pattern 109. Each of the electrode patterns 103, 104, and 109 provided on the substrate 101 is wire-bonded to the electrode sections (not shown) of the light emitting diode chips 108 with the metal wires 107 each having a diameter of several tens of micrometers. In the present embodiment, 20 of the light emitting diode chips 108 are connected with the above-mentioned electrode patterns 103, 104 and 109 via the metal wires 107 in such a way that the light emitting diode chips 108 are aligned in two serial lines to make 10 parallel arrangements.

The light emitting diode chips 108 arrayed as above are covered with the sealing resin section 105 as shown in FIG. 1. In the present embodiment, the sealing resin section 105 is formed with a silicon resin material. Further, as shown in FIG. 3, the fluorescent bodies 110 are dispersed in the sealing resin section 105. The fluorescent bodies 110 are, for example, preferably fluorescent bodies ((Sr, Ba, Ca)₂SiO₄ activated with bivalent europium, for example) which emits yellow light having a peak wavelength of 560 nm.

The sealing resin section 105 is formed as below, for example. A teflon resin having an opening through which a silicon resin material including fluorescent bodies is applied is attached to the substrate 101 via an adhesive sheet. Then, the silicon resin is applied by using a dispenser so that the silicon resin formed at the opening has a thickness of 0.4 mm. After the silicon resin applied inside a sheet becomes substantially leveled off, the resin is cured by heating in an oven at a precuring temperature of 100° C. for 1 hour, and further heating at a curing temperature of 150° C. for 4 hours. In this way, the sealing resin section 105 is formed.

Next, as shown in FIG. 1, a light scattering section for scattering light from the light emitting diode chips 108 is formed on at least part of the surface of the sealing resin section 105 thus formed. In the present embodiment, the light scattering section is a light scattering resin section 106 including a light scattering material. The light scattering resin section 106 scatters part of light from the light emitting diode chips 108 so as to return the light to the sealing resin section 105. Then, the fluorescent bodies 110 are excited by the light returned to the sealing resin section 105 so that fluorescence from the fluorescent bodies is emitted also outside the light emitting element 110. As a result, an amount of the light from the light emitting diode chips 108 decreases while an amount of the fluorescence increases, so that it becomes possible to adjust the chromaticity of the light emitting element. Note that the light scattering resin section 106 scatters not only the light emitted from the light emitting diode chips 108 but also the fluorescence from the fluorescent bodies 110 excited by the light from the light emitting diode chips 108. However, although the fluorescence returns to the sealing resin section 105 so as to reach the fluorescent bodies 110, a color of the fluorescence is not converted.

Next, a method for forming the light scattering resin section is described with reference to FIGS. 4(a) and 4(b). First, chromaticity of total number of the light emitting elements 100 is measured after the step for forming the sealing resin section 105. The chromaticity can be measured by a known method with a generally used colorimeter.

A result of the measurement is shown in FIG. 4(a). As shown in FIG. 4(a), light from the light emitting elements 100 before the light scattering resin section 106 is formed has a chromaticity variation that widely extends due to the variation in the dispersion of the fluorescent bodies 110 in the sealing resin section 105.

At this point, the light scattering resin sections 106 are formed in each of the light emitting elements whose chromaticity in the sealing resin section 105 is comparatively small (indicated in the area A in FIG. 4(a)) by applying a light scattering resin material including a light scattering material, and then curing the resin material. By this, as shown in FIG. 4(b), the chromaticity is adjusted due to the fluorescence from the fluorescent bodies excited by the light that is scattered by the light scattering resin section 106 and then is returned to the sealing resin section 105. As a result, a chromaticity variation indicated in the area A shown in FIG. 4(b) is cancelled out. That is to say, the range of the chromaticity variation can be narrowed to approximately half.

An arrangement for adjusting the chromaticity variation is more specifically described by referring a case of using blue light emitting diode chips and yellow fluorescent bodies. Part of blue light emitted by the light emitting diode chips 108 is scattered by the light scattering resin sections 106 so as to be returned to the sealing resin section 105. The fluorescent bodies 110 excited by the light returned to the sealing resin section 105 convert the blue light into yellow light, and then emit the yellow light. As a result, an amount of the blue light from the light emitting diode chips 108 decreases while an amount of the yellow light from the fluorescent bodies 110 increases. As a result, the chromaticity of light from the light emitting element becomes larger than that of a light emitting element without such an adjustment. Consequently, a variation in smaller chromaticity is shifted toward that in larger chromaticity so that the chromaticity variation among the light emitting elements 100 is adjusted.

In case where a light scattering resin section 106 is formed on a surface of a sealing resin section 105 as shown in a light emitting element 100 in FIG. 3, part of blue light (represented by the arrows in full line in FIG. 3) that is normally emitted from the surface of the sealing resin section 105 to an outside of the light emitting element 100 is scattered so as to return to the sealing resin section 105. Then, the returned light is absorbed in the fluorescent bodies 110 so as to be converted into yellow light (represented by the arrow in dashed line in FIG. 3). This results in an increase in a proportion of the blue light converted into the yellow light to the blue light emitted from the light emitting diode chips 108. In this way, chromaticity of light emitted outside the light emitting element 100 can be adjusted so as to be shifted from blue light to more yellow (to become greater in chromaticity).

A light scattering material included in such a light scattering resin section 106 is not particularly limited, and may preferably be barium titanate, barium sulfate, titanic oxide, aluminium oxide, silicon oxide, light calcium carbonate, or the like. Further, particles of the light scattering material may preferably be approximately 0.1 μm or more and 10 ∞m or less in diameter. Furthermore, a position on which the light scattering resin section 106 is formed is not particularly limited, however, it is not preferable to arrange the light scattering resin section 106 near an end of the sealing resin section 105 since a small amount of the light from the light emitting diode chips 108 arrives at the light scattering resin section 106 at the position.

Although an alumina substrate is used as the substrate 101 in the present embodiment, it is also possible to use an aluminium nitride substrate, a so-called enamel substrate, an aluminium substrate, and the like. The enamel substrate is obtained by coating, with a ceramic dielectric, a metal plate made of iron and the like, which has a high mechanical strength and a high heat conductivity. Further, the present invention can be modified in any way in terms of an electrode structure, an electrode pattern, a layout and the number of the light emitting diode chips 108, the number of arrangements in series/parallel of the light emitting diode chips 108, and the like.

Moreover, as described in the present embodiment, the light emitting diode chips 108 may have such an element structure that the light emitting diode chip 108 is mounted on an insulating substrate such as a sapphire substrate, and has a positive electrode and a negative electrode on its front surface, or that the light emitting diode chip 108 is mounted on a conductive substrate such as GaN and Si, and has a positive electrode and a negative electrode on its front and back surfaces. When such a light emitting diode chip 108 having the electrode on its back surface is used, the light emitting diode chip 108 may be mounted on a wiring pattern by using a conductive paste such as an Ag paste.

Further, the light emitting diode chips 108 and electrode patterns 103, 104, and 109 may form a contact structure with a flip flop mounted by solder bump. Moreover, the wavelength of the light emitting diode chips 108 is not limited to blue, but may be one that is not described in the present embodiment, such as 400nm range in the near ultraviolet region. Also, the color of the light emitted from the fluorescent bodies 110 is not particularly limited, provided that the light from the light emitting diode chips 108 can be absorbed. For example, it is possible to use such fluorescent bodies that convert the blue light into monochromatic light such as red light and green light.

### Second Embodiment

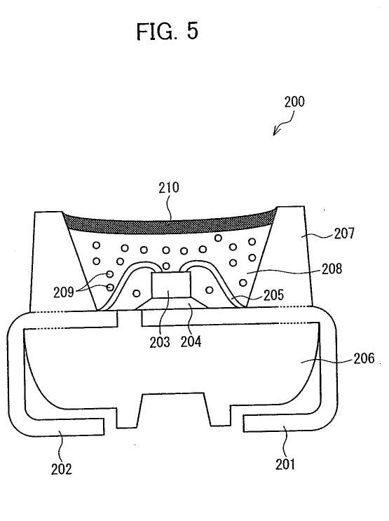

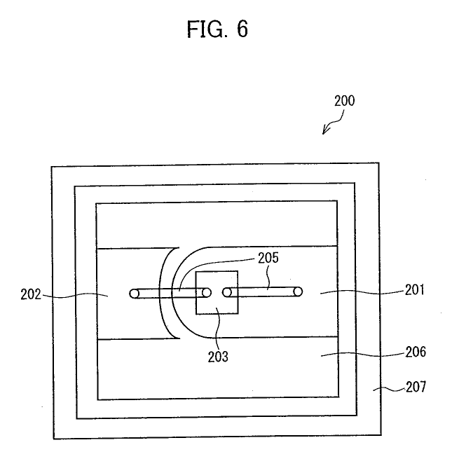

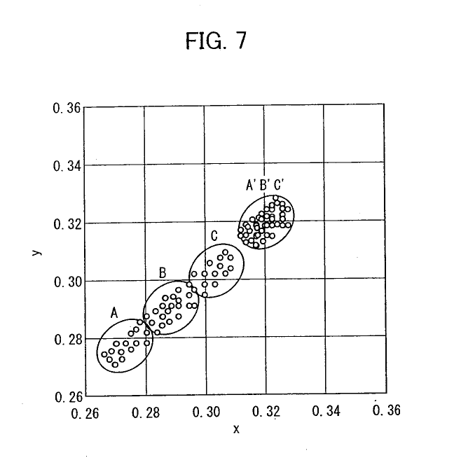

Another embodiment of the light emitting element in accordance with the present invention is described below with reference to FIGS. 5 through 7. FIG. 5 is a cross-sectional view of a light emitting element 200 in accordance with one embodiment of the present invention. FIG. 6 is a top view showing an inside of the light emitting element 200 shown in FIG. 5. FIG. 7 is a chromaticity diagram showing a chromaticity variation among the light emitting elements 200 shown in FIG. 5. Note that a specific explanation of the same member and structure as the first embodiment is omitted in the present embodiment.

As shown in FIGS. 5 and 6, the light emitting element 200 has a positive electrode section 201, a negative electrode section 202, a light emitting diode chip 203, a resin paste 204, metal wires 205, a resin mounting section 206, a reflector section 207, a sealing resin section 208, fluorescent bodies 209, and a light scattering resin section 210. The fluorescent bodies 209 are dispersed in the sealing resin section 208. Further, a light scattering material is dispersed in the light scattering resin section 210.

In the light emitting element 200, each of the positive electrode section 201 and the negative electrode section 202 is formed from a U-shaped metal, which is provided on a bottom surface side of the resin mounting section 206 and extends to a surface of the resin mounting section 206 on which the light emitting diode chip 203 is mounted. The electrode sections are made preferably from a metallic material having a high heat radiation, and copper alloy is suitably used as the metallic material, for example. This helps to release heat generated by the light emitting diode chip 203 so that it becomes possible to prevent degradation in reliability of a device caused by an increase in temperature of the light emitting element 200.

The light emitting diode chip 203 is die-bonded with the resin paste 204 to a surface of the resin mounting section 206 where the positive electrode section 201 is provided. A surface treatment for attaining a high light reflectance is preferably applied to that position on a surface of the resin mounting section 206 on which the light emitting diode chip 203 is die-bonded or on which the negative electrode section 202 is provided. For example, it is preferable that the surface is plated with silver. Further, an electrode pattern (not shown) are provided on an upper surface of the light emitting diode 5 chip 203 is wire-bonded to the surfaces of the resin mounting section 206 where the positive electrode section 201 is provided and where the negative electrode section 202, respectively, via the metal wire 205 having a diameter of several tens of micrometers.

On the surface of the resin mounting section 206 on which the light emitting diode chip 203 is mounted, the reflector section 207 is provided so as to surround the light emitting diode chip 203. An inner surface of the reflector section 207 inclines toward an outside of the light emitting element 200 from the resin mounting section 206 side. The reflector section 207 can be formed by an insert molding of polyphenylene amide resin, or the other method. Further, the reflector section 207 may include microparticles of titanic oxide in the resin and may be colored in white so that a reflectance ratio at the resin surface is increased. Furthermore, a reflective surface for reflecting light may be formed on the inner surface of the reflector section 207. The reflective surface can be formed with a film made of a material such as Ag, which increases the reflectance ratio.

The sealing resin section 208 including the fluorescent bodies 209 is formed inside the reflector section 207. The sealing resin section 208 can be formed by filling the inside of the reflector section 207 with an epoxy resin having a barrier property against gas and an excellent airtightness. In the present embodiment, fluorescent bodies ((Sr, Ba, Ca)₂SiO₄ activated with bivalent europium, for example) emitting yellow light having a peak wavelength of 560 nm are used for the fluorescent bodies 209.

An amount of the fluorescent bodies 209 in the sealing resin section 208 is arranged so that the largest value (the largest values of x and y) in a chromaticity distribution in case of including the fluorescent bodies 209 becomes smaller than a desired chromaticity. Further, a light scattering section for scattering light from the light emitting diode chip 203 is provided over the surface of the sealing resin section 208 including the fluorescent bodies 209. In the present embodiment, the light scattering section is the light scattering resin section 210 including a light scattering material. Note that the sealing resin section 208 and the light scattering resin section 210 may be formed with different resin materials.

In the present embodiment, chromaticity of light from each of the light emitting diode chips 203 in total number of the light emitting elements 200 is measured before the light scattering resin section 210 is formed. Then, formed is the light scattering resin section 210 in which an amount of light to be scattered is adjusted based on a measurement result of the chromaticity. First, the measurement result of the chromaticity is shown in FIG. 7. FIG. 7 is a view showing a chromaticity variation of light emitted from the light emitting elements 200 (light emitted from the surface of the sealing resin section 208) before the light scattering resin section 210 is formed. As shown in FIG. 7, the light emitting elements are categorized by their chromaticity regions represented by, for example, A, B, and C, based on the measurement result of the chromaticity.

Next, three types of resins having different concentrations of the light scattering material are prepared. The concentrations of the light scattering material are arranged so that each chromaticity in the regions A, B, and C shown in FIG. 7 becomes a desired chromaticity after the light scattering section 210 is formed. In the present embodiment, the concentrations are arranged so that each chromaticity in the regions A, B, and C shown in FIG. 7 becomes one represented as x=0.32 and y=0.32. These resins are preliminarily filled in dispensers. Then, each of the resins including the light scattering material in such an amount that gives the desired chromaticity is applied to the sealing resin section 208 that seals the light emitting diode chips 203 having chromaticity of the corresponding region. The resin is thereafter cured so that the light scattering section 210 is formed.

By this, although there is a wide chromaticity variation among the light emitting elements before the light scattering resin section 210 is formed, as shown by the regions A, B, and C in FIG. 7, it is possible to adjust the chromaticity in the regions A, B, and C to be in a region A′, B′, C′, respectively, by forming, in the light emitting elements each having a different chromaticity, the light scattering resin sections 210 each including a different concentration of the light scattering material. As a result, the chromaticity variation shown before the light scattering resin section 210 is formed can be reduced to about one third.

In the present embodiment, the amount of the fluorescent bodies 209 included in the sealing resin section 208 is arranged so that the largest value (the largest values of x and y) in the chromaticity distribution of the light emitting elements 200 before the light scattering resin section 210 is formed becomes smaller than the desired chromaticity. This makes it possible to control the center value of the chromaticity. That is to say, even if the center value of the chromaticity distribution is shifted to some extent, it is possible to attain more easily the center value of the finally desired chromaticity by accordingly controlling an amount of light scattered by the light scattering resin section 210.

Note that, although the chromaticity of the light emitting elements 200 before the light scattering resin section 210 is formed is divided into three regions in the present embodiment, the chromaticity can be divided into more regions, needless to say.

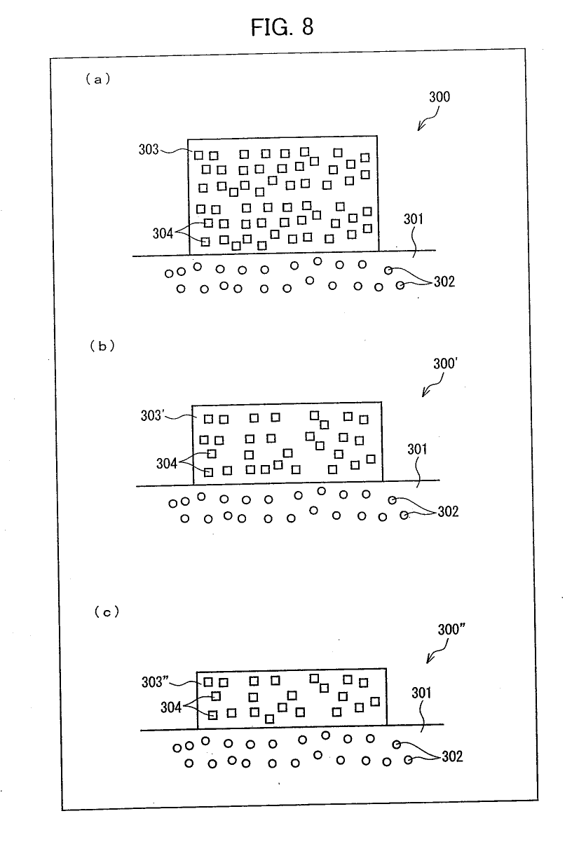

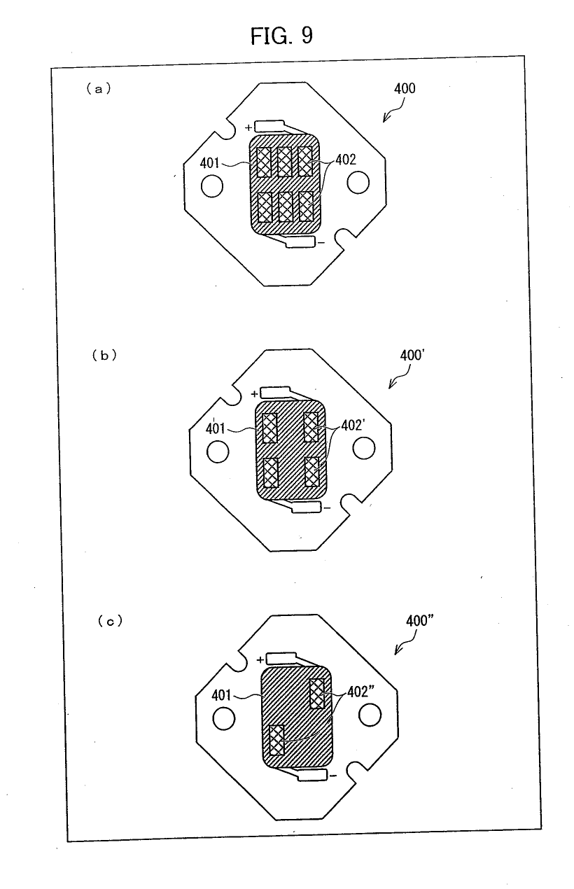

For the purpose of adjusting the chromaticity of the light emitting element, the amount of the scattered light may be adjusted by controlling a thickness or area of the light scattering resin section to be formed based on the measurement result of the chromaticity. FIGS. 8 and 9 show such embodiments of the light scattering resin section. FIG. 8 is partial sectional-views of light emitting elements 300. FIG. 9 is top views of light emitting elements 400. Note that the light emitting elements shown in FIGS. 8 and 9 include the same arrangement as the first embodiment, except the light scattering resin section.

As shown in FIG. 8, a thicker light scattering resin section 303 (FIG. 8(a)) is formed on a surface of a sealing resin section 301 provided on light emitting diode chips having a small chromaticity. A thinner light scattering resin section 303″ (FIG. 8(c)) is formed on a surface of a sealing resin section 301 provided on light emitting diode chips having a large chromaticity. This makes it possible to adjust the chromaticity variation and to control the center value of the chromaticity. The thickness of the light scattering resin section 303 can be controlled by accordingly changing an amount of a resin material to be applied to form the light scattering resin section 303. However, it is also possible to carry out steps for applying and curing the resin material so as to obtain a thickness that is individually optimized in response to the chromaticity of individual light emitting diode chip. For example, it is also possible to control the thickness by laminating resin plates of a certain thickness, which are preliminarily produced.

Further, as shown in FIG. 9, a light scattering resin section 402 (FIG. 9(a)) is arranged so as to be applied to a larger area on a surface of a sealing resin section 401 provided on light emitting diode chips having a small chromaticity. A light scattering resin section 402″ (FIG. 9(c)) is arranged so as to be applied to a smaller area on a surface of a sealing resin section 401 provided on light emitting diode chips having a large chromaticity. This makes it possible to adjust the chromaticity variation and to control the center value of the chromaticity. The area on which the light scattering resin section 402 is formed can be controlled by accordingly changing an amount of the resin material to be applied to form the light scattering resin section 402. However, it is also possible to carry out steps for applying and curing the resin material so as to obtain an area that is individually optimized in response to the chromaticity of individual light emitting diode chip. Additionally, the light scattering resin section is not particularly limited in shape, and may have various shapes such as a circle.

Moreover, the light scattering resin section 402 may be formed by directly applying the resin material including a light scattering material to the surface of the sealing resin section 401, instead, may be formed by preliminarily forming the resin material including the light scattering material with a metal mold into a plate shape of a certain size. The chromaticity is adjusted by changing the number of the plate-shaped light scattering resin sections 402 to be attached in response to the measurement result of the chromaticity. That is to say, it can be arranged so that a larger number of the light scattering resin sections 402 (FIG. 9(a)) are attached to the surface of the sealing resin section 401 provided on light emitting diode chips having a small, and a smaller number of the light scattering resin section 402″ (FIG. 9(c)) is attached to the surface of the sealing resin section 401 provided on light emitting diode chips having a large chromaticity.

This makes it possible to adjust the chromaticity variation and to control the center value of the chromaticity. A method for attaching the light scattering resin section is not particularly limited. However, it is preferable that the light scattering resin section is attached by using the same material as the resin material constituting the sealing resin section or the light scattering resin section since it is possible to prevent a light reflection occurred by differences in adhesiveness between the resins and in refractive index at the resin interface. Further, after an original resin plate is formed and then cut into a desired size, the light scattering resin section having different sizes can be formed based on the size of the resin plate.

### Third Embodiment

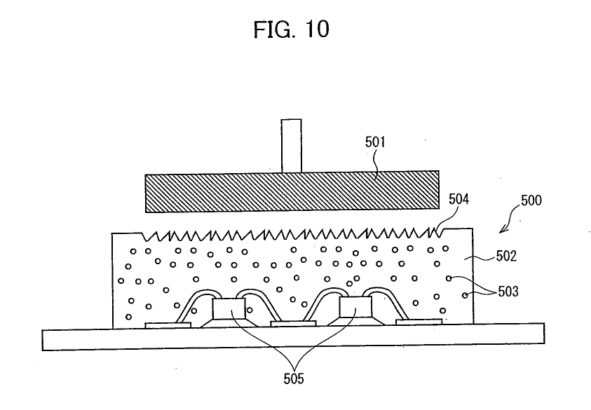

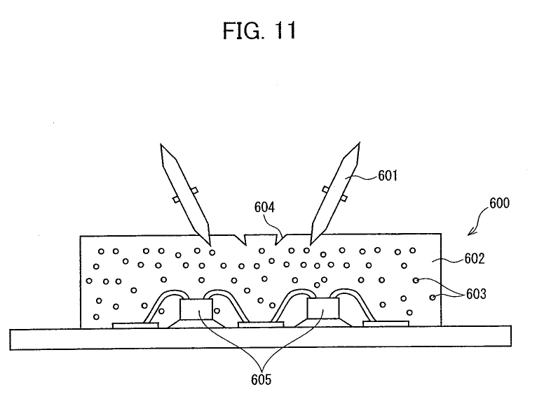

Still another embodiment of the light emitting element in accordance with the present invention is described below with reference to FIGS. 10 and 11. FIGS. 10 and 11 are schematic views showing a part of processes for forming light emitting elements 500 and 600 in accordance with the present invention, respectively. The present embodiment includes the same arrangement as the first embodiment, except the light scattering section.

As shown in FIG. 10, a surface of a sealing resin section 502 of a light emitting element 500 is ground by a disc-shaped grinding stone 501 having a grinding material made of alumina, thereby forming a light scattering section 504 having a rough-surfaced shape. The rough surface is formed so as to have a size that is at least same as the wavelength of visible light so that light can be effectively scattered. Further, a surface roughness Ra of the rough-surfaced shape formed in response to the chromaticity distribution of the light emitting elements 500, which chromaticity distribution is obtained before the light scattering section 504 is formed, is arranged so as to be same as or larger than the wavelength of visible light, that is, such the surface roughness Ra that is same as or larger than a wavelength of light from the surface of the sealing resin section 502. Consequently, it becomes possible to adjust chromaticity variation among the light emitting elements 500 and to control the center value of the chromaticity.

The surface roughness Ra of the rough-surfaced shape can be adjusted by changing the time for grinding or by changing the type of the grinding stone 501 for grinding. Specifically, the resin surface can be roughly ground by using a grinding stone having a grinding material having a large particle diameter, that is, a grinding stone having a rough surface, so that light scatters to a great extent on the resin surface. On the other hand, the resin surface can be finely ground by using a grinding stone having a grinding material having a small particle diameter, that is, a grinding stone having a fine surface, so that the light scatters to a small extent on the resin surface. Further, it is possible to adjust an area where the light scatters by using a plurality of disc-shaped grinding stones having the grinding material only in part thereof and having different areas.

As shown in FIG. 11, a groove having a triangular cross-section is linearly formed on a surface of a sealing resin section 602 of a light emitting element 600 by using a cutting blade 601, thereby forming a light scattering section 604. At this point, a width, a depth, and the number of the grooves and an interval between the grooves can be determined according to how much chromaticity needs to be adjusted. For example, five, six, or seven grooves each having a width of 1 mm and a depth of 0.1 mm are formed at intervals of 1.5 mm. This makes it possible to adjust chromaticity variation among the light emitting elements 600 and to control the center value of the chromaticity since oblique parts of the grooves reflect light differently from the surface of the sealing resin section 602. Further, such a cutting blade that makes the cross-section of the groove have a trapezoidal shape may be used so that the side surfaces of the trapezoid cause a change in reflectance ratio.

As described above, since the light emitting element in accordance with the present invention is a light emitting element having a light scattering section, for scattering light, provided on at least part of a surface of a sealing resin section covering light emitting diode chips, part of light to be emitted outside the light emitting element from the light emitting diode chips is scattered by the light scattering section and then is returned to the sealing resin section so as to excite fluorescent bodies so that fluorescence can be generated. Therefore, it is possible to adjust chromaticity of light from the light emitting element by controlling an amount of light scattered by the light scattering section, thereby suitably reducing a variation in the chromaticity.

The present invention can also be described as below.

(First Arrangement)

A light emitting element having at least light emitting diode chips and a resin section, in which at least one or more type of fluorescent bodies are dispersed, the resin section covering the light emitting diode chips, the light emitting element having a structure, provided on at least one area on a surface of the resin section, for scattering light from the light emitting diode chips in order to adjust chromaticity of the light emitting element.

(Second Arrangement)

The light emitting element according to First Arrangement, having (i) blue light emitting diode chips as the light emitting diode chips, (ii) an alumina substrate, on which the blue light emitting diode chips are mounted, having an electrode pattern formed on at least one area on the substrate surface on which area the blue light emitting diode chips are not mounted, (iii) metal wires connecting the electrode pattern to each electrode section provided on an upper surface of the blue light emitting diode chip, and (iv) the resin section formed so as to cover the blue light emitting diode chips, the light emitting element having a structure, provided on at least one area on a surface of the resin section, for scattering light from the light emitting diode chips in order to adjust chromaticity of the light emitting element.

(Third Arrangement)

The light emitting element according to First Arrangement, having (i) blue light emitting diode chips as the light emitting diode chips, (ii) a resin substrate, on which the blue light emitting diode chips are mounted, having (a) an electrode pattern formed on at least one area on the substrate surface on which area the blue light emitting diode chips are not mounted, (b) an electrode structure connected to the electrode pattern and provided at the bottom of the resin substrate, and (c) a reflector section, made from a resin having a well-like shape, provided on the resin substrate so as to cover the blue light emitting diode chips, (iii) metal wires connecting the electrode pattern to each electrode section provided on an upper surface of the blue light emitting diode, and (iv) a resin section formed so as to cover the blue light emitting diode chips and to fill the reflector section, the light emitting element having a structure, provided on at least one area on a surface of the resin section, for scattering light from the light emitting diode in order to scatter chromaticity of the light emitting element.

(Fourth Arrangement)

The light emitting element according to one of First to Third Arrangements, wherein the structure for scattering light is made from a transparent resin in which a light scattering material is dispersed.

(Fifth Arrangement)

The light emitting element according to one of First to Third Arrangements, wherein the structure for scattering light is such that rises and falls are irregularly positioned on the resin section in which the fluorescent bodies are dispersed, the rises and falls causing the structure to have a surface roughness Ra that is equal to or larger than the wavelength of visible light.

(Sixth Arrangement)

The light emitting element according to Fifth Arrangement, wherein one or more grooves that have a substantially uniform cross-section is provided so as to form a stripe on the surface of the resin section.

(Seventh Arrangement)

A method for producing a light emitting element, including, the steps of: (a) producing a resin section of the light emitting element; and (b) forming, on the resin section, a light scattering structure for scattering light emitted from the light emitting diode chips, the step (a) including: applying and curing a resin in which fluorescent bodies are dispersed, so that light emitting diode chips are covered; and measuring chromaticity after the resin is cured, and the step (b) forming the light scattering structure in response to the chromaticity.

(Eighth Arrangement)

The method according to Seventh Arrangement, wherein the step (b) includes applying and curing a resin A on that surface of a resin B on which the fluorescent bodies are applied, the resin A containing a light scattering material dispersed therein.

(Ninth Arrangement)

The method according to Seventh Arrangement, wherein the step (b) includes forming a resin in an adjusted thickness, the resin containing a light scattering material of a certain concentration dispersed therein.

(Tenth Arrangement)

The method according to Seventh Arrangement, wherein the step (b) includes forming a resin having a predetermined area, the resin containing a light scattering material dispersed at an adjusted concentration therein.

(Eleventh Arrangement)

The method according to Seventh Arrangement, wherein the step (b) includes forming a resin having an adjusted area, the resin containing a light scattering material of a certain concentration dispersed therein.

(Twelfth Arrangement)

The method according to Seventh Arrangement, wherein the step (b) includes grinding a surface of the resin section by using a grinding material.

(Thirteenth Arrangement)

The method according to Seventh Arrangement, wherein the step (b) includes forming grooves in stripe on a surface of the resin section by using a blade.

(Fourteenth Arrangement)

The method according to one of Seventh to Thirteenth Arrangements, wherein an amount of the fluorescent bodies dispersed in the resin section is arranged so that a largest value in a chromaticity variation measured after the resin in which the fluorescent bodies are dispersed is applied and cured becomes smaller than the center value of a desired chromaticity.

The present invention is not limited to the description of the embodiments above, but may be altered within the scope of the claims. An embodiment based on a proper combination of technical means disclosed in different embodiments is encompassed in the technical scope of the present invention.

As described above, since the light emitting element in accordance with the present invention has a light scattering section, for scattering light, provided on at least part of a surface of a first resin section covering light emitting diode chips, part of light to be emitted outside the light emitting element from the light emitting diode chips is scattered by the light scattering section. Among the scattered light, light that returns to the first resin section excites fluorescent bodies. In this way, it is possible to adjust chromaticity variation in the light emitting elements.

The light emitting element in accordance with the present invention can be suitably used in a lighting apparatus, a liquid crystal device, and the like, since light having a small variation in chromaticity can be attained.

It is preferable to arrange the light emitting element in accordance with the present invention so that the light scattering section includes a second resin section including a light scattering material. Further, it is preferable to arrange the light emitting element in accordance with the present invention so that the light scattering section has a rough-surfaced shape having a surface roughness Ra that is equal to or larger than the wavelength of visible light. In addition, it is preferable to arrange the light emitting element in accordance with the present invention so that the light scattering section has at least one groove. With the arrangements, it is possible to control an amount of light from the light emitting diode chips reflected by the surface of the first resin, and to reduce the chromaticity variation.

Further, it is preferable to arrange the light emitting element in accordance with the present invention so that the first resin section includes such an amount of the fluorescent bodies that the largest value in variation of chromaticity of light emitted from a surface of the first resin section is smaller than a desired chromaticity (In the present specification, a chromaticity value closer to, one indicative of a color of light emitted only by the light emitting diode chips is referred to as small chromaticity, meanwhile, a chromaticity value closer to one indicative of a color of light emitted only by the fluorescent bodies is referred to as large chromaticity. The largest value in variation means a value that is closest to one indicative of the color of the light emitted by the fluorescent bodies).

In order to adjust an amount of the light to be scattered, the light scattering section is formed so that light from the light emitting diode chips returns to the first resin section. This cause light emitted from the fluorescent bodies to increase. In consequent, the chromaticity of light emitted from the first resin section can be adjusted to be larger. As described above, in the light emitting element before the light scattering section is formed, the chromaticity of the light emitted from the first resin section is arranged so as to be within the range of a variation of chromaticity that is smaller than a desired chromaticity. This enables to control the center value of chromaticity of light emitted from the light emitting elements. That is to say, even if the center value of the chromaticity distribution is shifted to some extent, it is possible to attain the center value of the finally desired chromaticity by accordingly adjusting the amount of light scattered by the light scattering section.

Moreover, the light emitting element in accordance with the present invention may be arranged so that the first resin section is surrounded by a reflector section that reflects light at its surface.

It is preferable to arrange the method for producing the light emitting element in accordance with the present invention so as to further include: measuring chromaticity of light emitted from the surface of the first resin section, the step for forming the light scattering section including controlling an amount of light scattered by the light scattering section to be formed, in response to the chromaticity measured in the step for measuring the chromaticity.

With the arrangement, the chromaticity of light emitted from the surface of the first resin section is measured before the light scattering section is formed. In response to the measurement result, an amount of light scattered by the light scattering section to be formed is adjusted. This enables to adjust more precisely the chromaticity variation. In consequent, the chromaticity variation is reduced. This makes it possible to produce more easily a light emitting element capable of emitting light having the desired chromaticity.

Moreover, it is preferable to arrange the method so that the light scattering section includes a second resin section including a light scattering material; and the step for forming the light scattering section includes adjusting a thickness of the second resin section in response to the chromaticity measured in the step for measuring the chromaticity. Further, it is preferable to arrange the method so that the light scattering section includes a second resin section including a light scattering material; and the step for forming the light scattering section includes adjusting an amount of the light scattering material included in the second resin section in response to the chromaticity measured in the step for measuring the chromaticity. In addition, it is preferable to arrange the method so that the light scattering section includes a second rein section including a light scattering material; and the step for forming the light scattering section includes adjusting, on the surface of the first resin section, an area on which the second resin section is formed in response to the chromaticity measured in the step for measuring the chromaticity. With the arrangements, it is possible to easily form the light scattering section in which the amount of light to be scattered is adjusted in response to the chromaticity of light from the light emitting elements, which is measured before the light scattering section is formed. As a result, it is possible to produce more easily the light emitting elements having a small chromaticity variation.

Further, it is preferable to arrange the method so that the light scattering section has a rough-surfaced shape; and the step for forming the light scattering section includes adjusting a surface roughness Ra of the rough-surfaced shape in response to the chromaticity measured in the step for measuring the chromaticity, so as to be equal to or larger than a wavelength of light emitted from the surface of the first resin section. Furthermore, it is preferable to arrange the method so that the light scattering section has a groove; and the step for forming the light scattering section includes adjusting the groove in terms of width, depth, number, and interval therebetween in response to the chromaticity measured in the step for measuring the chromaticity. With the arrangements, it is possible to easily form the light scattering section in which the amount of light to be scattered is adjusted in response to the chromaticity of light from the light emitting elements, which is measured before the light scattering section is formed. As a result, it is possible to produce more easily the light emitting elements having a small chromaticity variation.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

What is claimed is:

1. A light emitting element comprising light emitting diode chips and a first resin section including fluorescent bodies and covering the light emitting diode chips, the light emitting element comprising:
a light scattering section provided on at least part of a surface of the first resin section, the light scattering section being configured to scatter light.

2. The light emitting element according to claim 1, wherein the light scattering section includes a second resin section including a light scattering material.

3. The light emitting element according to claim 1, wherein the light scattering section has a rough-surfaced shape having a surface roughness Ra that is equal to or larger than the wavelength of visible light.

4. The light emitting element according to claim 1, wherein the light scattering section has at least one groove.

5. The light emitting element according to claim 1, wherein the first resin section includes such an amount of the fluorescent bodies that the largest value in a variation of chromaticity of light emitted from a surface of the first resin section is smaller than a desired chromaticity.

6. The light emitting element according to claim 1, wherein the first resin section is surrounded by a reflector section that reflects light at its surface.

7. A method for producing a light emitting element having light emitting diode chips and a first resin section including fluorescent bodies and covering the light emitting diode chips, the method comprising:
forming a light scattering section on at least part of a surface of the first resin section, the light scattering section being configured to scatter light.

8. The method according to claim 7, further comprising:
measuring chromaticity of light emitted from the surface of the first resin section,
the step for forming the light scattering section including controlling an amount of light scattered by the light scattering section to be formed, in response to the chromaticity measured in the step for measuring the chromaticity.

9. The method according to claim 8, wherein:
the light scattering section includes a second resin section including a light scattering material; and
the step for forming the light scattering section includes adjusting a thickness of the second resin section in response to the chromaticity measured in the step for measuring the chromaticity.

10. The method according to claim 8, wherein:
the light scattering section includes a second resin section including a light scattering material; and
the step for forming the light scattering section includes adjusting an amount of the light scattering material included in the second resin section in response to the chromaticity measured in the step for measuring the chromaticity.

11. The method according to claim 8, wherein:
the light scattering section includes a second resin section including a light scattering material; and
the step for forming the light scattering section includes adjusting, on the surface of the first resin section, an area on which the second resin section is formed, in response to the chromaticity measured in the step for measuring the chromaticity.

12. The method according to claim 8, wherein:
the light scattering section has a rough-surfaced shape; and
the step for forming the light scattering section includes adjusting a surface roughness Ra of the rough-surfaced shape in response to the chromaticity measured in the step for measuring the chromaticity, so as to adjust the surface roughness Ra to be equal to or larger than a wavelength of light emitted from the surface of the first resin section.

13. The method according to claim 8, wherein:
the light scattering section has a groove; and
the step for forming the light scattering section includes adjusting the groove in terms of width, depth, number and interval therebetween in response to the chromaticity measured in the step for measuring the chromaticity.
